(19) United States
(12) Patent Application Publication
(10) Pub. No.: US 2023/0297742 A1
(43) Pub. Date: Sep. 21, 2023

(54) ARTIFICIAL INTELLIGENCE-BASED SYSTEM IMPLEMENTING PROXY MODELS FOR PHYSICS-BASED SIMULATORS

(71) Applicant: C3.ai, Inc., Redwood City, CA (US)

(72) Inventors: Philippe Ivan S. Wellens, Moraga, CA (US); Amir Hossein Delgoshaie, Palo Alto, CA (US)

(21) Appl. No.: 17/699,395

(22) Filed: Mar. 21, 2022

(51) Int. Cl. G06F 30/27

(52) U.S. Cl. CPC G06F 30/27

(57) ABSTRACT

A simulation method includes providing a physics-based simulation model including model parameters for simulating a physical process using input data from different sources of operational data including time series data, the physics-based simulation model generating output data including simulated predictions that are calculated using the model parameters, an artificial intelligence (AI)-based-system including an AI-based proxy model. The AI-based proxy model responsive to receiving an update of the input data processes the updated input data to generate a proxy prediction for at least one selected prediction from the simulated predictions or a variable derived from the simulated prediction as a replacement for or as a supplement to the selected prediction or the variable derived from the selected prediction.

### FIELD

Disclosed aspects relate to tuning or supplementing of physics-based simulators.

### BACKGROUND

Industrial customers conventionally use physics-based simulation software, such as MATLAB simulink, Ansys FLUENT, JEWELSUITE, PETREL or KBC PETROSIM, which may also be referred to as being a physics engine. Physics-based simulation software is computer software run on a suitable high-speed computer that provides an approximate simulation for a variety of different physical systems, such as rigid or soft body dynamics, and fluid dynamics. The term physics-based simulation software is sometimes used more generally to describe any software system for simulating a physical phenomena. A proxy model is a mathematically or statistically defined model that replicates or approximates the response of the outputs of a full-scale simulation model for some selected input parameters of the simulation model.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed aspects recognize there is believed to be no system that can jointly manage physics-based simulation models from different vendors and combine them with data-driven Artificial Intelligence (AI) proxy models. Physics-based simulation model vendors traditionally offer their solution as standalone software. They typically do not provide uncertainty quantification, the ability to incorporate prior knowledge, joint parameter tuning independent of the governing physical laws, proxy model training, and data ingestion. They also do not support connecting physics-based simulation models from different vendors.

One disclosed aspect comprises a simulation method. The simulation method comprises providing at least one physics-based simulation model including model parameters for simulating a physical process using input data from a plurality of different sources of operational data including time series data. The physics-based simulation model generates output data comprising simulated predictions that are calculated using the model parameters. Also provided is an AI-based-system including at least one AI-based proxy model and an optional normalization engine.

The normalization engine is for normalizing at least a portion of the input data to generate normalized input data that is all time aligned and in a uniform format. The AI-based proxy model responsive to receiving an update of the input data processes the updated input data to generate a proxy prediction for at least one selected prediction from the simulated predictions or a variable derived from the simulated prediction as a replacement for or as a supplement to the selected prediction or the variable derived from the selected prediction.

### BRIEF DESCRIPTION OF THE DRAWINGS

FIG. 1 is a flow chart that shows steps in an example simulation method system utilizing a disclosed AI-based system implementing an AI-based proxy model for generating proxy predictions for at least one selected prediction from the simulated predictions of a physics-based simulator or a variable derived from the selected prediction, according to an example aspect.

FIG. 2A depicts an example simulation system including a disclosed AI-based system implementing an AI-based proxy model, according to an example aspect.

FIG. 2B depicts an example simulation system including a disclosed AI-based system implementing an AI-based proxy model for generating proxy predictions for at least one selected prediction from the simulated predictions of a physics-based simulator or a variable derived from the selected prediction for use as a replacement for or as a supplement to the selected prediction or the variable derived from the selected prediction, according to an example aspect.

FIG. 3 is a block diagram representation for an example computing system that can be used to implement a disclosed AI-based system implementing an AI-based proxy model and disclosed simulation methods, according to an example aspect.

### DETAILED DESCRIPTION

Disclosed aspects are described with reference to the attached figures, wherein like reference numerals are used throughout the figures to designate similar or equivalent elements. The figures are not drawn to scale and they are provided merely to illustrate certain disclosed aspects. Several disclosed aspects are described below with reference to example applications for illustration. It should be understood that numerous specific details, relationships, and methods are set forth to provide a full understanding of the disclosed aspects.

Provided below is a glossary of some terms used herein:

Operational data includes both structured and unstructured data (e.g., time series, images, videos, PDFs, text, sound) coming from a variety of data sources which are relevant to the process(es) modeled by the physics-based simulation model(s). For example, operational data can comprise the telemetry data from various sensors on an industrial machine, along with images, video and text from maintenance reports for various sections of the machine.

A physics-based simulation model is a mathematical model for a physics-based system that runs a physical process having model parameters for receiving input data and in response generating output data using the model parameters comprising simulated predictions.

A physical process is a process involving at least one physical system, and can involve a tangible material, or not involve a tangible material such as in the case of modeling for light. An example of a physical process is a physics-based process involving tangible material, with physics-based process examples involving tangible material including production from an oil and gas field, air flow around an airplane, and the trajectory of a rocket.

Model parameters are used by a physics-based simulation model together with variables for simulating (making predictions for) a physical process using input data from a plurality operational data sources. The model parameters in the case of a polynomial equation that can be a first order or higher order equation are the coefficients (constants) of the equation or weights in the case of a neural network.

Simulated predictions are generated as outputs by a physics-based simulation model that are calculated using the model parameters and variables, for example a prediction for temperature or velocity of a fluid that uses an equation including the variables and model parameters as the constant coefficients including for the variables.

Time series data is a sequence of data points spanning a period of time, such as when received from a sensor.

Normalization is a feature that transforms raw time series data into a more structured/cleansed time series signal and stores it in a datastore for faster data access on reads that is used herein before data analysis performed by the AI-based proxy model. Consider ingesting data from a plurality of Internet of Things (IoT) sensors containing duplicate values, overlapping values, missing values, and/or values of random length, where not every data point might span same time period. To draw any meaningful analysis, by exploration, charting, and/or machine learning, it is recognized herein that this time series data needs to be converted into a structured format. A normalization engine converts the raw time series data points into structured/normalized time series data which are cleansed, unit converted, deduped, de-overlapped, interpolated, and/or interval aligned. Operating on such normalized data simplifies ad hoc analysis, charting and use in machine learning algorithms, including for use in the disclosed AI-based proxy models.

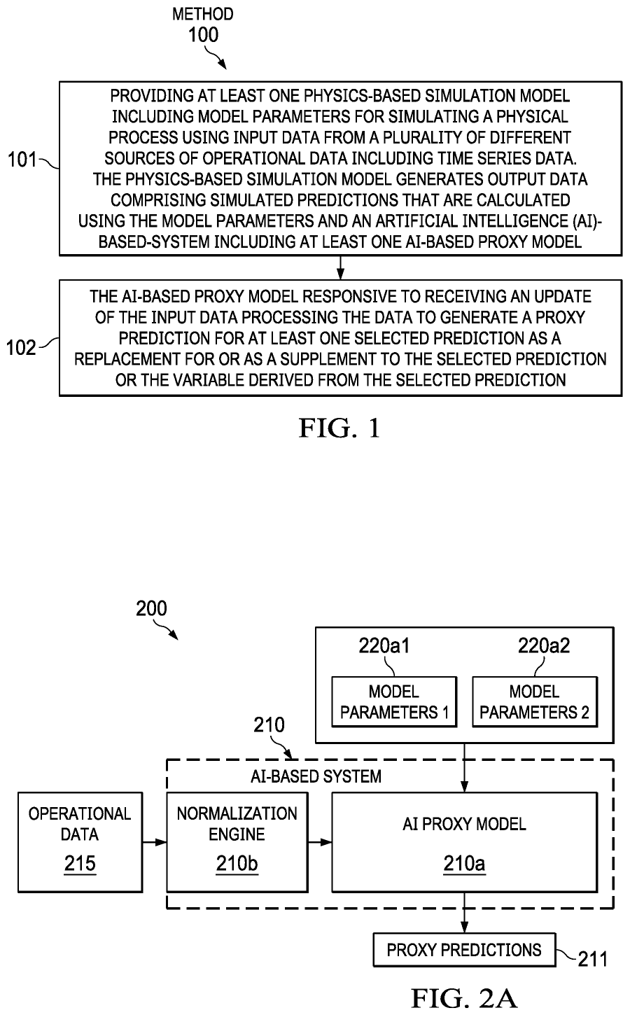

FIG. 1 is a flow chart that shows steps in an example simulation method 100. Step 101 comprises providing at least one physics-based simulation model including model parameters for simulating a physical process using input data from a plurality of different sources of operational data including time series data. As described above the operational data can also include images, videos, PDFs, text, and sound. The physics-based simulation model generates output data that is calculated using the model parameters comprising simulated predictions. Also provided is an AI-based-system including at least one AI-based proxy model. The AI-based system can also include an optional normalization engine.

Step 102 comprises the AI-based proxy model responsive to receiving an update of the input data processes the updated input data to generate a proxy prediction for at least one selected prediction from the simulated predictions or a variable derived from the simulated predictions as a replacement for or as a supplement to the selected prediction or the variable derived from the selected prediction.

The update of the input data can optionally be available on a predefined schedule. The method can further comprise the AI-based system training the AI-based proxy model based on at least a portion of pairs of the input data and the output data resulting from the input data to provide a trained AI-based proxy model. As examples regarding pairs of the input data and the resulting output data, for a given input X1, the simulation model(s) predicts an output y1. Similarly for two different inputs say X2, X3, the simulation model can predict different outputs y1, y2, and y3. X1, y1 is a pair of input data and resulting output data. X2, X3, and y1, y2, y3 is also considered to be a pair of input and resulting output data.

At least one physics-based simulation model can comprise a first physics-based simulation model and a second physics-based simulation model that are not integrated together. These two simulation models can also be two simulators from the same vendor that are designed separately and are not integrated with each other. For the simulation models to not be integrated together it means there is no communication or exchange of data between the respective simulation models. Alternatively, the respective physics-based simulation models can be integrated together, where for example some vendors provide simulation software that are compatible and in communication with each other such that the input/output of one simulation model or part of its input/output can be read and fed to the second simulation model by design. The first simulation model can be obtained from a first vendor and the second simulation model can be obtained from a second vendor that is different from the first vendor.

The AI-based system can provide an uncertainty quantification for the proxy prediction. For the uncertainty quantification one can use Bayesian analysis and variational inference or other methods, and prior knowledge integration. Prior knowledge means what is the previous belief about a particular model parameter. This prior knowledge can be based on a measurement, subject matter expertise, or results from another simulation model. A Bayesian inference is a known method of statistical inference in which Bayes' theorem is used to update the probability for a hypothesis as more evidence or information becomes available so that a Bayesian inference is the form of machine learning (ML).

The proxy prediction can comprise a measurable, where generally at least some of the simulated predictions are measurable, where the method can further comprise comparing a measurement value of the measurable to the proxy prediction, and based on the comparing changing a value of one of the model parameters. A proxy prediction can be provided for all of the model parameters. The proxy predictions can be used as a replacement (an alternative) to the simulated predictions to run the physical process. The proxy prediction(s) can also be used as a supplemental (together with) the simulated predictions to run the physical process. For a supplemental example, the AI-based proxy model can use the simulated predictions as input data to predict/detect an event, such as to detect abnormal behavior of the simulated predictions/outputs.

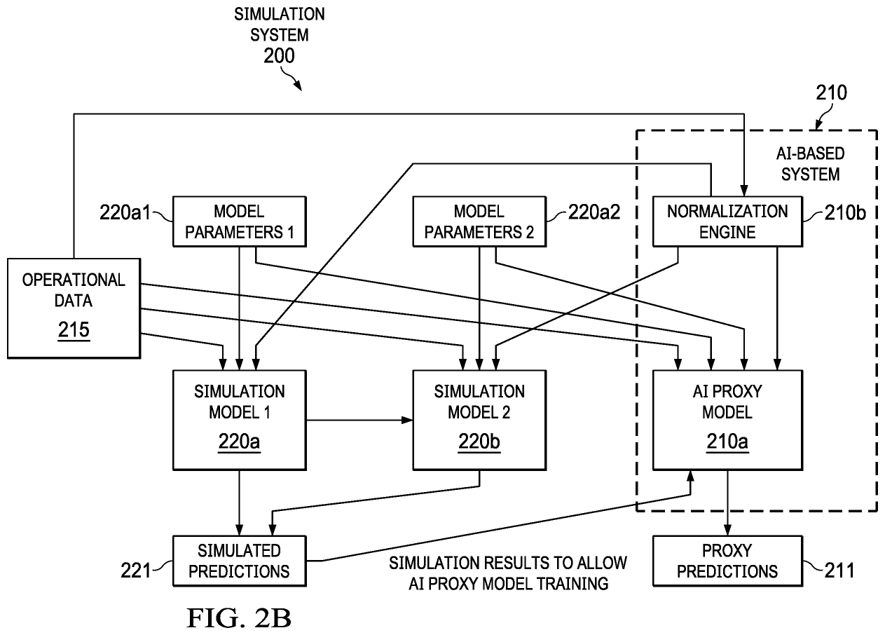

FIG. 2A depicts an example simulation system 200 including a disclosed AI-based system 210 implementing an AI-based proxy model 210a that provides proxy predictions 211 and an optional normalization engine 210b for normalizing at least a portion of the input data to generate normalized input data that is all time aligned and in a uniform format. Model parameters 220a1 and 220b1 for respective physics-based simulation models are shown provided to the AI-based proxy model 210a, that can optionally share the same model parameters, where the physics-based simulation models are for simulating a physical process using input data from a plurality of different sources of operational data shown collectively as operational data 215 that is also shown provided to the AI-based system 210. As described below relative to FIG. 2B, the physics-based simulation models are configured to receive the operational data 215 and to generate output data referred to as being simulated predictions, where the simulated predictions are provided to the AI-based proxy model 210a.

The normalization engine 210b is configured to receive, ingest and then process the operational data 215 for normalizing including preprocessing time series data comprising time aligning for at least a portion of the operational data 215. The normalization engine 210b can also optionally normalize the model parameters provided they are a function of time.

FIG. 2B depicts an example simulation system 200 including a disclosed AI-based system 210 implementing an AI-based proxy model 210a and an optional normalization engine 210b. The AI-based proxy model is for generating proxy predictions for at least one selected prediction from the simulated predictions of a physics-based simulator or a variable derived from the selected prediction for use as a replacement for or as a supplement to the selected prediction or the variable derived from the selected prediction, according to an example aspect. The physics-based simulation model is shown optionally including two physics-based simulators shown as 220a and 220b.

The physics-based simulation models 220a and 220b include respective model parameters 220a1 and 220b1, that as described above can optionally share the same model parameters, for simulating a physical process using operational data 215 as its input data from a plurality of different sources of operational data. The physics-based simulation models 220a and 220b are configured to receive the operational data 215 and to generate output data using the model parameters comprising shown collectively as simulated predictions 221. The simulated predictions 221 are provided to the AI-based proxy model 210a.

The normalization engine 210b is shown providing its normalized data results to the AI-based proxy model 210a and to the physics-based simulation models 220a and 220b. As described above, the AI-based proxy model 210a responsive to receiving an update of the operational data 215 processes the updated input data to generate a proxy prediction 211 for at least one selected prediction from the simulated predictions or a variable derived from the selected prediction. The proxy prediction(s) can be used as a replacement for or as a supplement to at least one selected prediction from the simulated predictions 221, which is generally a plurality of proxy predictions 211. For example, the proxy prediction can be for one of the simulated predictions (e.g., a temperature or a fluid flow rate value), or a value derived from this selected prediction, such as for a risk/anomaly score derived from a temperature value prediction.

Disclosed aspects include a computer-based system that implements an AI-based system 210 including a data-driven AI-based proxy model which can connect and manage multiple physics-based (mathematical) simulation models. Disclosed computer-based systems enable customers to generally obtain significantly more value out of their existing physics-based simulation models and to augment and productionize them with AI that utilizes data that comes from measurements from the physics-based system, such as sensor measurements, described as being operational data, generally provided by the customer.

The operational data does not necessarily need to be all real-time or near real-time data or include real-time or near real-time data. Typically as soon as there is new (updated) operational data, it is generally desirable to update the AI-based proxy model to reflect the new measurements and updated proxy predictions. Besides real-time operational data, historical operational data can also be used in whole or in part together with the real-time operational data.

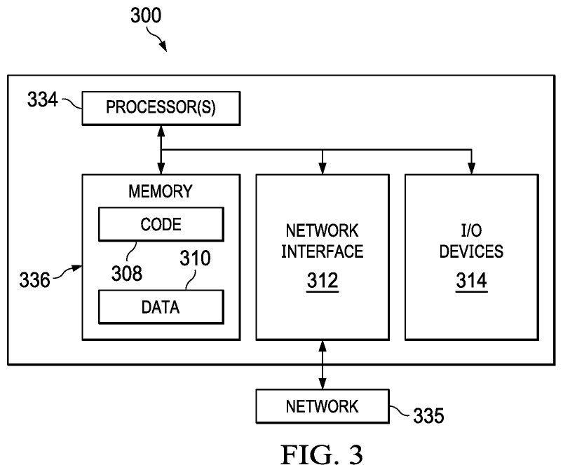

FIG. 3 is a block diagram representation for an example computing system 300 that can implement a disclosed AI-based system 210 and disclosed methods, according to an example aspect. The computing system 300 may be located on-site or remote, including the cloud. The computing system 300 includes at least one processor 334, such as a microprocessor or digital signal processor (DSP), that is coupled to a memory 336, a network interface 312, and input/output (I/O) devices 314. The computing system 300 may comprise a uniprocessor system including one processor 334, or a multiprocessor system including a plurality of processors 334. In general, processors 334 may be any suitable processor capable of executing instructions. For example, in various aspects, processors 334 may be general-purpose or embedded microprocessors implementing any of a variety of instruction set architectures (ISAs).

The memory 336 generally comprises a non-transitory, computer-readable storage medium configured to store program instructions of code 308 and historical data 310 accessible by the processor(s) 334, shown as memory 336. The memory 336 may comprise static random-access memory (SRAM), synchronous dynamic RAM (SDRAM), nonvolatile/flash-type memory, or generally any other type of memory. Code 308 and data 310 for implementing the functionality disclosed herein are stored within the memory 336. For example, the code 308 may include instructions that when executed by processor(s) 334 implement disclosed operations described above.

The network interface 312 may be configured to allow data to be exchanged between the computing system 300 and/or other devices coupled to the network 335, such as telemetry data servers (e.g., OSIsoft PI). The network interface 312 may support communication via wired or wireless data networks, such as any suitable type of Ethernet network or wireless network.

In general, I/O devices 314 may include one or more display terminals, keyboards, keypads, touchpads, scanning devices, voice or optical recognition devices, or any other devices suitable for entering or retrieving data associated with the computing system 300. Multiple I/O devices 314 may be provided. Similar I/O devices may be separate from the computing system 300 that may interact with the computing system 300 through a wired or wireless connection, such as over the network interface 312.

A disclosed AI-based system 210 significantly reduces the time needed to generate predictions and to change (update/calibrate) at least one of the model parameters by building data-driven AI-based proxy models. Regarding the building (or training) of the data-driven AI-based proxy models, over the lifetime a mathematical simulator such as a physics-based simulation model, it utilizes a plurality of inputs used to make predictions for process parameters and other non-measurable parameters (collectively outputs). By storing respective input and output pairs a training set can be generated and used to train the data-driven AI-based proxy model to act as a fast surrogate model.

The disclosed AI-based system can be set up in a relatively short timeframe and it automatically tunes the physics-based simulation model(s) using continuously ingested operational data 315 from the assets under management by the customer in order to maintain all simulation models up to date, and, in the case of multiple physics-based simulation models, in synchronization. Moreover, disclosed aspects can provide uncertainty estimations and integrate prior knowledge for the predictions of both the physics-based simulation models and the data-driven AI-based proxy models. Also, the AI-based system enables non-surrogate data-driven AI-based proxy models to generate predictions which use physics-based or data-driven AI-based proxy model outputs as inputs and leverage both time series and unstructured data. Finally, the computer-based system enables expanding beyond the scope of each individual physics-based simulation model to make systemwide decisions for running process for large interconnected systems.

Disclosed AI-based systems abstract away each physics-based simulation model in a way that the inputs and outputs of the different physics-based simulation models can be made to be compatible with each other. The disclosed AI-based system can act as a single source of truth for the latest and most up to date input data from all different operational data sources utilized for the different models. Moreover, the disclosed AI-based systems can handle multiple computer programs executing on computer hardware for each physics-based emulation model and transfer and/or share data between these programs.

It is to be understood that the computing system 300 is only an example and is thus not intended to limit the scope of any disclosed aspect. For example, the computing system 300 may include any combination of hardware or software that can perform the functions disclosed herein, including computers, network devices, internet appliances, PDAs, and wireless phones. The computing system 300 may also be connected to other devices that are not illustrated. In addition, the functionality provided by the illustrated components may be combined in fewer components, or be distributed in additional components.

1. A simulation method comprising:
providing at least one physics-based simulation model with input data from a plurality of different sources of operational data, the at least one physics-based simulation model including model parameters for simulating a physical process;
generating output data comprising simulated predictions using the at least one physics-based simulation model, the simulated predictions determined using the model parameters; and
using an artificial intelligence (AI)-based system including at least one AI-based proxy model that is responsive to receiving an update of the input data, processing the input data to generate a proxy prediction for at least one selected prediction from the simulated predictions or a variable derived from the at least one selected prediction as a replacement for or as a supplement to the at least one selected prediction or the variable derived from the at least one selected prediction.

2. The simulation method of claim 1, wherein:
the proxy prediction comprises a measurable; and
the method further comprises comparing a measurement value of the measurable to the proxy prediction and, based on the comparing, changing a value of one of the model parameters.

3. A simulation method comprising:
providing at least one physics-based simulation model with input data from a plurality of different sources of operational data, the at least one physics-based simulation model including model parameters for simulating a physical process;
generating output data comprising simulated predictions using the at least one physics-based simulation model, the simulated predictions determined using the model parameters;
normalizing at least a portion of the input data using a normalization engine to generate normalized input data that is time-aligned and in a uniform format; and
using an artificial intelligence (AI)-based system including at least one AI-based proxy model that is responsive to receiving an update of the input data, (i) processing the normalized input data to generate updated normalized input data, and (ii) processing the updated normalized input data to generate a proxy prediction for at least one selected prediction from the simulated predictions or a variable derived from the at least one selected prediction as a replacement for or as a supplement to the at least one selected prediction or the variable derived from the at least one selected prediction.

4. The simulation method of claim 3, wherein the update of the input data is available on a predefined schedule.

5. The simulation method of claim 3, further comprising:
using the AI-based system to train the at least one AI-based proxy model based on at least a portion of pairs of the normalized input data and the output data resulting from the normalized input data.

6. The simulation method of claim 3, wherein the at least one physics-based simulation model comprises a first physics-based simulation model and a second physics-based simulation model that are not integrated together.

7. The simulation method of claim 3, wherein the AI-based system further provides an uncertainty quantification for the proxy prediction.

8. The simulation method of claim 3, wherein:
the proxy prediction comprises a measurable; and
the method further comprises comparing a measurement value of the measurable to the proxy prediction and, based on the comparing, changing a value of one of the model parameters.

9. The simulation method of claim 3, wherein the proxy prediction is provided for all of the model parameters.

10. The simulation method of claim 3, wherein the proxy prediction is used as the replacement for the at least one selected prediction to run the physical process.

11. The simulation method of claim 3, wherein the proxy prediction is used as the supplement to the at least one selected prediction by combining the proxy prediction with the at least one selected prediction to run the physical process.

12. A system comprising:
at least one processor configured to:
obtain input data from a plurality of different sources of operational data;
use at least one physics-based simulation model to generate output data comprising simulated predictions, the at least one physics-based simulation model including model parameters for simulating a physical process, the at least one physics-based simulation model configured to generate the output data using the model parameters; and
use an artificial intelligence (AI)-based system including at least one AI-based proxy model that is responsive to an update of the input data to process the input data to generate a proxy prediction for at least one selected prediction from the simulated predictions or a variable derived from the at least one selected prediction as a replacement for or as a supplement to the at least one selected prediction or the variable derived from the at least one selected prediction.

13. A system comprising:
at least one processor configured to:
use a normalization engine to normalize at least a portion of input data to generate normalized input data that is time-aligned and in a uniform format, the input data comprising data from a plurality of different sources of operational data and used by at least one physics-based simulation model to generate output data comprising simulated predictions, the at least one physics-based simulation model including model parameters for simulating a physical process, the at least one physics-based simulation model configured to generate the output data using the model parameters; and
use an artificial intelligence (AI)-based system including at least one AI-based proxy model that is responsive to an update of the input data to (i) process the normalized input data to generate updated normalized input data, and (ii) process the updated normalized input data to generate a proxy prediction for at least one selected prediction from the simulated predictions or a variable derived from the at least one selected prediction as a replacement for or as a supplement to the at least one selected prediction or the variable derived from the at least one selected prediction.

14. The system of claim 13, wherein the update of the input data is available on a predefined schedule.

15. The system of claim 13, wherein the at least one processor is further configured to use the AI-based system to train the at least one AI-based proxy model based on at least a portion of pairs of the normalized input data and the output data resulting from the normalized input data.

16. The system of claim 13, wherein the at least one physics-based simulation model comprises a first physics-based simulation model and a second physics-based simulation model that are not integrated together.

17. The system of claim 13, wherein the AI-based system is configured to provide an uncertainty quantification for the proxy prediction.

18. The system of claim 13, wherein:
the proxy prediction comprises a measurable; and
the at least one processor is further configured to compare a measurement value of the measurable to the proxy prediction and, based on the comparison, change a value of one of the model parameters.

19. The system of claim 13, wherein the at least one processor is configured to provide the proxy prediction for all of the model parameters.

20. The system of claim 13, wherein the at least one processor is configured to use the proxy prediction as the replacement for the at least one selected prediction to run the physical process.

21. The system of claim 13, wherein the at least one processor is configured to use the proxy prediction as the supplement to the at least one selected prediction by combining the proxy prediction with the at least one selected prediction to run the physical process.
